(19) United States
(12) Patent Application Publication
(10) Pub. No.: US 2006/0267600 A1
(43) Pub. Date: Nov. 30, 2006

(54) System for purifying and monitoring the condition of lubricant fluid in compressors and other equipment

(76) Inventor: Daryl L. Beatty, Lake Jackson, TX (US)

Correspondence Address: THE DOW CHEMICAL COMPANY, INTELLECTUAL PROPERTY SECTION,, P. O. BOX 1967, MIDLAND, MI, 48641-1967, US

(21) Appl. No.: 10/547,557

(22) PCT Filed: Apr. 15, 2004
(86) PCT No.: PCT/US04/11715

§ 371 Date: Aug. 30, 2005

Related U.S. Application Data
(60) Provisional application No. 60/463,454, filed on Apr. 16, 2003.

(51) Int. Cl. G01R 27/08

(52) U.S. Cl. 324/698

(57) ABSTRACT

A system for the in-situ purification and monitoring of the condition of a lubricant fluid used in a rotary screw or centrifugal air compressor is described. The system is functionally incorporated into the rotary screw or centrifugal air compressor and comprises at least one filter device capable of removing an acid from the lubricant fluid, an electrical probe for electronically monitoring the condition of the lubricating fluid and communicating electrical signal to an electrical signal processing means, and an electrical signal processing means for processing electrical signal received from the electrical probe and alerting to the need for the change of the filter device or the lubricating fluid.

The present invention relates to a system for the in-situ removal of an organic acid and, if desired, a particulate matter from lubricant fluid while it circulates through a rotary screw or centrifugal air compressor said system being functionally incorporated into the rotary screw or centrifugal air compressor and comprising a disposable filter component, means for electronically monitoring the condition of the lubricating fluid and means for alerting to the need for the change of the disposable filter component or the lubricating fluid itself. The present invention also relates to a method for removal of the organic acid from the lubricating fluid and extending the life thereof by functionally incorporating the aforementioned system into the rotary screw or centrifugal air compressor.

Rotary screw air compressors became widely available in the United States in the 1970's, and by the 1980's had largely displaced reciprocating air compressors in the market for new industrial equipment. The lubrication needs for these compressors were unique in that the fluid served not only to lubricate the compressor, but also to seal rotors and function as a heat transfer fluid. Because of the exposure to large volumes of air and moisture at elevated temperatures, the oxidative stress on the lubricant is severe. Oxidation of the fluids led to “varnish” formation, which in turn plugged coolers and bearing passages in compressors, resulting in equipment failures. In addition, the low flash points of the commonly used petroleum oils at that time were accompanied by a high incidence of flash fires in compressors. In the 1980's the first generation of synthetic fluids developed specifically to address the needs of rotary compressors became widely used. Polyoxyalkylene glycol/ester blends, taught by U.S. Pat. No. 4,302,343, typically extended the fluid change interval from 1,000 to 8,000 hours, also eliminating the problems associated with varnish in the petroleum oils. By 1985, these polyoxyalkylene glycol/ester blend fluids were adopted as standard factory fill by the two largest US air compressor companies, and continue in widespread use to the present. Rotary compressor development in the 1990's resulted in smaller oil sump capacities and higher pressures and temperatures in some machines. Machines were also equipped with microprocessors/computers to monitor many parameters, such as pressure, loading, hours of use, and temperatures, and to give alarms when conditions warranted. Recent proliferation of microprocessors in equipment has resulted in increased interest in fluid condition monitoring. The patent literature describes the use of condition monitoring equipment, for various purposes.

U.S. Patent Application No. 20020011095A1 (Park et al) describes the use of a capacitive dielectric sensor for purpose of measurement of oil viscosity and contamination in an engine.

U.S. Pat. No. 5,754,055 (McAdoo et al) teaches the use of a coaxial microwave resonator in a fluid to measure changes in debris concentration to monitor for ferro-magnetic wear metals.

U.S. Pat. No. 5,604,441 (Freese et al) discloses a method for detection of ferromagnetic wear particles by capacitance measurement.

U.S. Pat. No. 5,656,767 (Garvey et al) describes a method for determination of the type of lubricant and the relative quantity of water present, by means of a capacitive sensor.

U.S. Pat. No. 5,224,051 (Johnson) teaches a method for remotely monitoring the condition of metalworking fluids, using four separate sensors.

U.S. Pat. No. 5,071,527 (Kauffman) describes an analytical technique involving the measurement of conductance, relating this to oxidation state of a lubricant.

Notably, one area that had never been addressed by those who developed the instrumentation is extension of fluid life by incorporating the well-established measurement technology into a system to remove acid from a fluid, and notify a user of the need for service.

Another area of technological development impacting rotary screw air compressors is the extension of fluid life by acid removal. Early efforts at the regeneration of lubricants by acid removal were primarily directed toward phosphate esters in gas and steam turbines and various large hydraulic system applications. Phosphate esters are particularly susceptible to degradation to form phosphoric acid. These systems initially employed activated alumina, zeolite, or Fullers earth to absorb or neutralize the acids. Further development in these systems resulted in development of twin column systems utilizing anionic exchange resins, which allow filtration of the lubricant in one of the columns, while the other is regenerated. These systems apparently work well with phosphate esters and polyol esters in hydraulic and gas turbine applications, but are bulky and complex, requiring manual or automated systems to switch back and forth between columns, and determine the state of regeneration of the ion exchange media. Such a system is thoroughly described in U.S. Pat. No. 5,661,117 (Dufresne). This patent also goes into greater detail concerning the background of the use of ion exchange resins, and the initial development of that basic technology. The utility of ion exchange resins in the absorption or neutralization of acids in phosphate ester and polyol ester lubricants is also well established in the other three publications cited.

The use of ion exchange resins in moisture and acid removal, particularly in phosphate ester fluids, and in refrigeration systems is well known, as referenced in Japanese Patent No. 2507160 B2, U.S. Pat. No. 5,661,117, and International Patent Application Publication No. WO94/25550. These current systems for phosphate esters and polyol ester hydraulic fluids typically include all or some of these components: a (1) resin drying system, (2) twin regenerative systems, and (3) controls and (4) valving to select between the two column systems. Alternatively, the fluid is removed from service, filtered and reinstalled. Because of that complexity, these units are predominantly found on large hydraulic systems. These systems have been shown to work very well in these applications, but are bulky, and complex, requiring manual or automated systems to switch back and forth, and determine the state of regeneration of the ion exchange media. Relatively complex systems such as described in U.S. Pat. No. 5,661,117 have been very satisfactory for large equipment, with very large fluid capacities, as great as 5000 gallons, which were not limited in space and received frequent attention to service. These systems would not be cost effective or suitable for rotary air compressors, primarily because of the complexity, size, and cost. A rotary compressor sump will typically range from two to sixty gallons in capacity. Also, the practicality of a complex purification system in smaller equipment with small sump capacities, and with restricted space, such as rotary screw air compressors is questionable.

Japanese Patent No. 2507160 B2 notes another very different use of ion exchange resins specific to use within refrigeration systems operating on R-134a refrigerant. In that application, acids formed by decomposition of the lubricant or refrigerant will be removed. In this application, the resin is enclosed in the sealed system, with the intention that it never be changed. Such a system is very different from a system such as a rotary screw air compressor, which is continually ingesting and forming acid, and would require some form of media replenishment.

Of present concern and application is the adaptation of ion exchange technology to practical use in rotary and centrifugal compressors. The state of the art when using polyoxyalkylene glycol and polyoxyalkylene glycol/ester blend compressor lubrication in rotary screw compressors is to simply run compressor fluid until fluid analysis shows the need for a fluid change, based on increase in Total Acid Number (TAN). Filtration presently used on current compressors is only particulate filtration, and does not incorporate acid removal by means of ion exchange. Lubricant fluid is typically changed at 8000 hour or one year intervals, or more frequently in hot or contaminated environments. Several auxiliary particulate removal filters are available, which operate off the sidestream or “kidney loop” filtration principle. These filters however, do not reduce TAN with polyglycol fluids, and do not incorporate ion exchange resins, but are designed and effective only for particulate removal.

In addition, there were two obstacles preventing the utilization of existing ion exchange technology in smaller equipment with lesser sump capacities. The effective function of the ion exchange media is to a large degree dependent on the presence of some water in the system. Most lubricant applications are nearly anhydrous. Also, the existing fleet of rotary compressors would require extensive piping modifications for use with systems such as those described in the prior art, making them non-functional from a practical standpoint. Enclosures surrounding most compressors also make the installation of large auxiliary equipment difficult or impractical, if possible at all.

The need to reduce and conserve the drain on natural resources, and the drive to reduce maintenance on compressors is an additional compelling force toward the need for a compressor system where fluid changes are greatly reduced, or even eliminated. Finally, the fusion of these areas of technology is necessary to achieve a system such as that described herein, which eliminates or greatly reduces the need for fluid changes in rotary screw compressors.

In one aspect the present invention is a system for the in-situ purification and monitoring of the condition of a lubricant fluid used in a rotary screw or centrifugal air compressor said system being functionally incorporated into the rotary screw or centrifugal air compressor and comprising (a) at least one filter device capable of removing an acid from the lubricant fluid, (b) an electrical probe for electronically monitoring the condition of the lubricating fluid and communicating electrical signal to an electrical signal processing means, and (c) an electrical signal processing means for processing electrical signal received from the electrical probe and alerting to the need for the change of the disposable filter device or the lubricating fluid.

In another aspect the present invention is a filter device capable of removing an acid from the lubricant fluid as it circulates through a system using a lubricating or hydraulic fluid such as, for example, a rotary screw or centrifugal compressor, a motor vehicle, hydraulic equipment or a construction equipment, said filter device comprising (a) a canister housing, (b) an ion exchange resin inside the canister housing and enclosed by a fine metal mesh at each inlet to allow lubricant fluid ingress and egress, (c) at least one lubricant fluid inlet, (d) lubricant fluid outlet, and (e) an O-ring around circumference of the filter device to seal it up to a system's mounting hardware.

In another embodiment the present invention is a filter device capable of removing an acid from the lubricant fluid as it circulates through a system using lubricating or hydraulic fluid such as, for example, a rotary screw or centrifugal compressor, a motor vehicle, hydraulic equipment or a construction equipment, said filter device comprising (a) a canister housing, (b) an ion exchange resin inside the canister housing and enclosed by fine metal mesh at each inlet to allow lubricant fluid ingress and egress, (c) a standard particulate filter media inside the canister housing and surrounded by the ion exchange resin, (d) at least one lubricant fluid inlet, (e) lubricant fluid outlet, and (f) an O-ring around circumference of the filter device to seal it up to a system's mounting hardware.

Still in another aspect the present invention is a method for the in-situ purification and monitoring the condition of a lubricant fluid of a rotary screw or centrifugal air compressor said method comprising passing the lubricant fluid through the system comprising (a) at least one filter device capable of removing an acid from the lubricant fluid, (b) an electrical probe for electronically monitoring the condition of the lubricating fluid and communicating electrical signal to an electrical signal processing means, and (c) an electrical signal processing means for processing electrical signal received from the probe and alerting to the need for the change of the disposable filter device or the lubricating fluid itself.

Still in another aspect, the present invention is the method for the in-situ purifying a lubricant fluid of a rotary screw or centrifugal air compress, said method comprising passing the lubricant fluid through at least one filter device comprising (a) a canister housing, (b) an ion exchange resin inside the canister housing and enclosed by fine metal mesh at each inlet to allow lubricant fluid ingress and egress, (c) at least one lubricant fluid inlet, (d) lubricant fluid outlet, and (e) an O-ring around circumference of the filter device to seal it up to a compressor mounting hardware.

Still in another aspect, the present invention is the method for the in-situ purifying a lubricant fluid of a rotary screw or centrifugal air compressor said method comprising passing the lubricant fluid through at least one filter device comprising (a) a canister housing, (b) an ion exchange resin inside the canister housing and enclosed by fine metal mesh at each inlet to allow lubricant fluid ingress and egress, (c) a standard particulate filter media inside the canister housing and surrounded by the ion exchange resin, (d) at least one lubricant fluid inlet, (e) lubricant fluid outlet, and (f) an O-ring around circumference of the filter device to seal it up to a compressor mounting hardware.

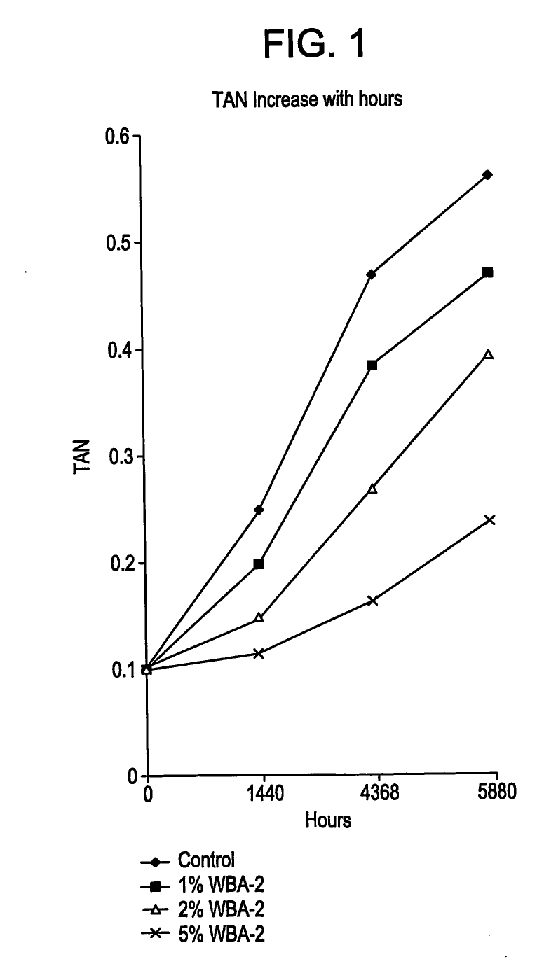

FIG. 1 is a graphical representation of the Total Acid Number (TAN) of a polyglycol compressor lubricant, held static in the presence of varying amounts of DOWEX™ WBA-2 resin at 120° C., demonstrating the efficacy of the resin in moderating TAN increase over time.

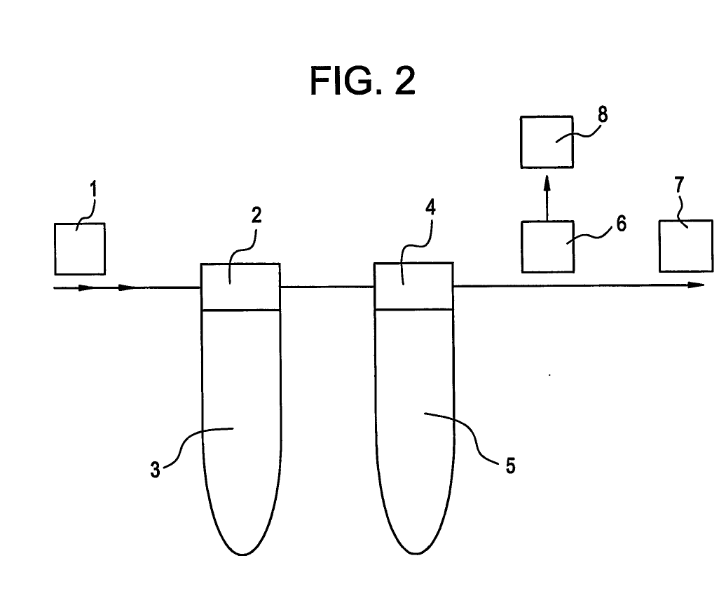

FIG. 2 is a schematic diagram illustrating a preferred method of fluid flow piping for a compressor utilizing separate particulate filter (3) and acid removal filter (5). This system would be most effective for new compressors.

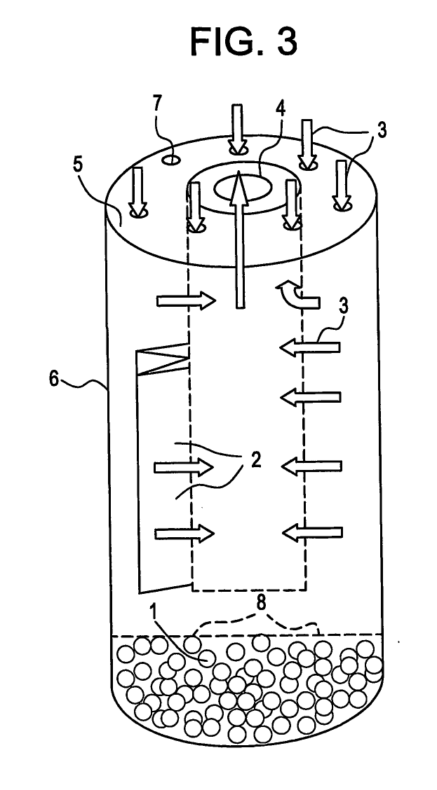

FIG. 3 is a cross-sectional diagram illustrating the embodiment of the filter device of the present invention capable of performing the dual functions of particulate filtration and acid removal.

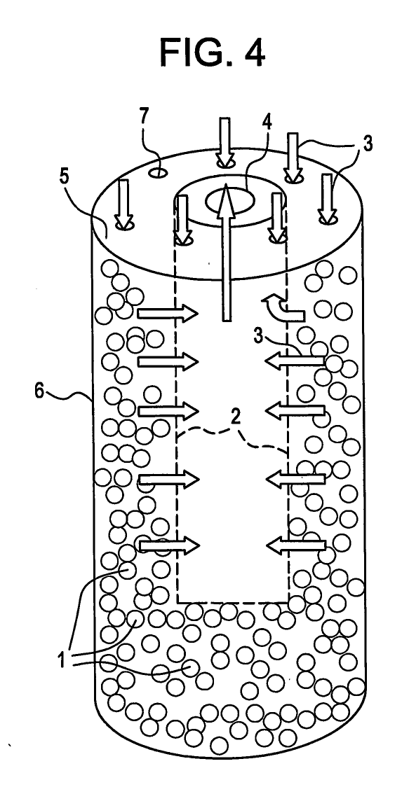

FIG. 4 is a cross-sectional diagram illustrating the embodiment of the filter device of the present invention containing only ion exchange resin, which is contained at the inlet and outlet by a fine mesh screen.

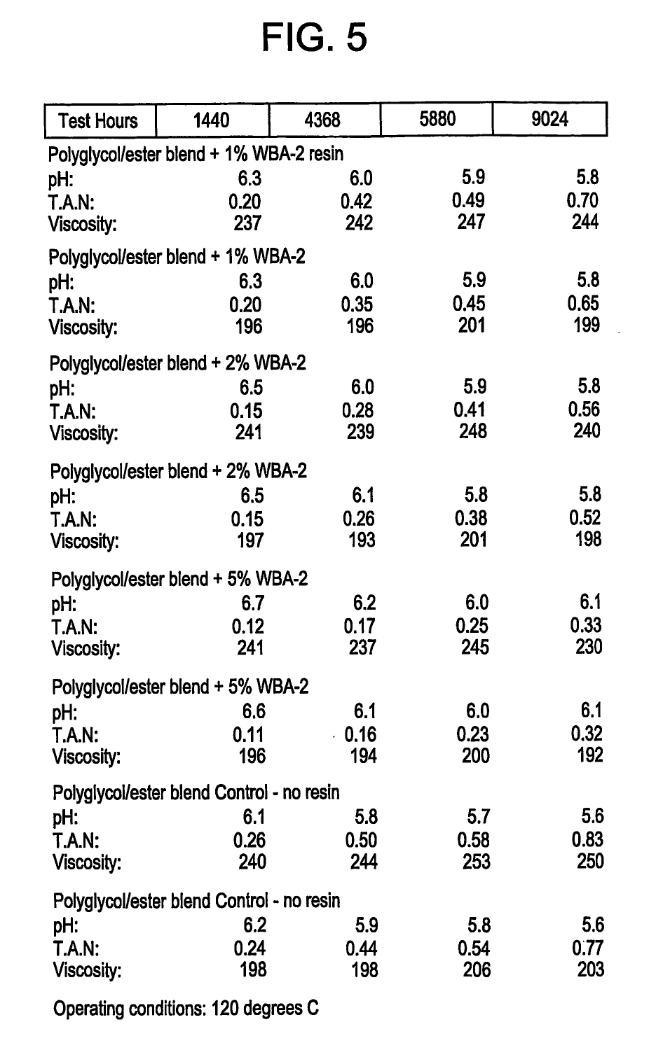

FIG. 5 is a table providing the performance results of long-term efficacy testing over a period of 9000 hours with varying levels of ion exchange resin.

As illustrated in FIG. 2, the lubricant fluid circulates in the closed loop formed by the compressor (1) and the system of the present invention into the acid removal filter device (3), then into the particulate filter device (5) and back into the compressor (7) in the direction indicated by arrows. The lubricant fluid enters and exits the particulate filter via filter mounting head hardware (4) and enters and exits the acid removal filter via a filter mounting head hardware (2). Only a portion of the fluid circulates to the acid removal filter, the balance bypassing this filter on to the particulate filter. The system also contains, downstream of the acid removal filter device, an electrical probe (6) capable of determining the capacitance, dielectric constant, or dissipation factor to monitor the condition of the lubricant fluid and alerting means (8) to alert the operator of the need to change the filter device(s) or the lubricant fluid.

FIG. 3 illustrates the filter device of the present invention capable of performing the dual functions of particulate filtration and acid removal. It comprises a housing (6) in the form of a steel canister, an ion exchange resin (1) situated in the bottom part of the steel canister and contained in woven wire mesh (8), a standard pleated particulate filter (2) situated above the ion exchange resin, one or more lubricant fluid inlets (7), lubricant fluid outlet (4), and the O-ring (5) around circumference of the filter device to seal it up to mounting hardware. Arrows (3) indicate direction of lubricant fluid flow. The lubricant outlet (4) is standard screw connection to allow easy replacement of the filter device. The particulate filter may be of pleated or spun material, or any other particulate filter media.

FIG. 4 illustrates the filter device of the present invention containing only ion exchange resin. It comprises a housing (6) in the form of a steel canister, an ion exchange resin (1) enclosed by fine metal mesh at each inlet (7) to allow lubricant fluid ingress and egress, a wire mesh resin retainer (2) surrounded by the ion exchange resin, one or more lubricant fluid inlets (7), lubricant fluid outlet (4), and the O-ring (5) around circumference of the filter device to seal it up to mounting hardware. Arrows (3) indicate direction of lubricant fluid flow. The lubricant outlet (4) is standard screw connection to allow easy replacement of the filter device. This filter device may be utilized in conjunction with a separate particulate filter to be located downstream and is most useful on new compressors.

The filter device may be a spin-on filter device or any other type of a replaceable filter device.

The ion exchange media suitable for used in the filter device of the present invention may be of any type suitable for the absorption of acid, preferably without releasing metal ions into the lubricant. Non-limiting example of suitable ion exchange media is DOWEX™ WBA-2 resin, sold by the Dow Chemical Company.

This invention also involves the use of the monitoring and measurement means to achieve the best results. The monitoring and measurement means can be any known device capable of determining the capacitance, dielectric constant, or dissipation factor of the compressor lubricant fluid and sending the electrical signals to the on-board microprocessor/computer for processing. Suitably, any known in line capacitance or conductivity probe, capable of determining the capacitance, dielectric constant, or dissipation factor of the compressor lubricant can be used in the present invention. A Non-limiting example of the capacitance probe is the Thermo Measurement brand capacitance probe model 420. The probe is preferably installed in the direct passage of the lubricant flow, more preferably downstream from the particulate filter device. The capacitance probe feeds a variable voltage or current signal to the existing compressor microprocessor, which compares the signal to preset alarm points for changing filter devices or lubricant fluid. The measurement of the capacitance property has been determined to give a reading bearing a reliable and direct relationship to the Total Acid Number (TAN) of the lubricant. The output from this device is readable as an input to the microprocessor that controls other functions of the compressor. The microprocessor systems currently used include the Intellysis™ system on Ingersoll-Rand compressors and “Supervisor 2” system on Sullair Compressors. Other known microprocessor systems can also be used in the practice of the present invention. These controllers are already used to monitor operating temperatures, air pressure, filter differential pressures, and other compressor operating parameters. The present invention uses the electronic output of a capacitance probe as an input to the controller, which is then programmed to alarm when a high TAN condition occurred. Upon alarm, an acid neutralizing ion-exchange filter, or the fluid itself could be changed. Integral to this invention is an acid removal filter suitable for rotary air compressors, and a long life polyoxyalkylene glycol/ester compressor fluid.

The present invention provides a lubricant system where the compressor fluid itself may never need changed in normal use. Even in extremely contaminated applications, much longer life would accrue, although in difficult applications, the fluid might eventually need changed. In all cases, the monitoring system would make the user aware that the acid removal filters or lubricant fluid need to be changed. The present invention involves the incorporation of the measurement of dielectric strength, conductivity, capacitance, or other similar electrical properties into the existing electronic control system of a compressor to determine when to change a rotary screw air compressor fluid. Further, the invention incorporates this type of monitoring, with an acid removal filter, into a system to greatly extend, or eliminate fluid changes in rotary screw air compressors.

The benefit of the system of the present invention results from a combination of a long life fluid, acid removal filtration, and lubricant fluid condition monitoring to achieve indefinite fluid life in a rotary screw or centrifugal air compressor. The benefit is accomplished by incorporation of the following four elements: (a) the use of an extended life lubricant fluid that may include polyoxyalkylene glycol, ester, or polyoxyalkylene glycol/ester blend, or other types, formulated for effective corrosion protection, and oxidation stability; (b) the use of an ion exchange resin filter to continuously remove traces of acid from the lubricant fluid; and (c) the use of a probe to monitor the condition of the acid removal filter device and determine the need for change of the acid filter device itself by monitoring the electrical properties of the fluid, such as conductivity, capacitance, or dielectric constant.

The present invention can be used in rotary screw and centrifugal air compressors using any type of lubricant fluid but is particularly suitable for use in the compressors using a long life lubricant fluid. Non-limiting examples of suitable long life lubricant fluids are polyoxyalkylene glycols, polyol esters, blends of polyoxyalkylene glycols and polyol esters, and polyalphaolefins. Preferably, the present invention is used in compressors with a blend of 50 percent to 70 percent polyoxyalkylene glycol and 30 percent to 50 percent polyolester lubricant fluid, effectively stabilized with additives such as an antioxidant package, anti-wear, corrosion inhibitors, metal passivators, antifoam agents, and air-release agent.

Polyoxyalkylene glycol and polyol ester lubricants as well as blends thereof are distinct among synthetic lubricant basestocks, in that acid accumulation is the dominant factor preventing indefinite use. These fluids do not experience an extreme increase in viscosity with extended use, and do not form varnish when properly formulated, but do continuously form acids. Also, these lubricant fluids will respond to increased oxidation change in electrical properties. The same ion exchange media, for example, when tested with a synthetic hydrocarbon fluid (PAO), had a significant benefit, and resulted in retention of low TAN, and prevention of discoloration. However, the fluid may still gain viscosity because of cross-linking or “varnish” formation. These failure mechanisms may not be as readily detected by measurement of electrical properties.

The failure mechanisms of cross-linking, varnish formation, and extreme viscosity increase are not characteristic of properly formulated polyglycol or polyglycol/ester blended lubricants. But without the anionic exchange resin filtration, even a long life polyglycol/ester type fluid will eventually need changed. When coupled with the small amount of make up fluid normally added to a compressor, the ion exchange resin filter can eliminate or greatly reduce the need for fluid changes.

The principle of ion exchange and its application to phosphate esters and a limited range of other fluids are well known. Also, use of variations on cartridge filter elements for particulate removal is present on every modern automobile. The present unique invention is the application of filters containing ion exchange media to new and novel use, in a rotary screw or centrifugal air compressor, especially where installation space is limited and to provide a practical method for retrofitting existing equipment. Further, the present invention provides the unique benefits of a simple system comprised of a disposable filter device which performs the dual purpose of particulate filtration and acid removal, resulting in longer lubricant fluid and compressor life. This invention is especially beneficial when used with polyglycol, ester, and polyglycol/ester blended lubricants in yielding a “fill-for-life” system for compressors.

The effective function of the ion exchange media is to a large degree dependent on the presence of some water in the system. Most lubricant applications are nearly anhydrous. Rotary screw air compressors, when utilized with polypropyleneglycol, polyol ester or blends of the two fluids are unique in that water concentration in the lubricant will be stabilized between 1000 and 3000 parts per million (ppm), depending on the operating temperature and the ambient humidity. This level of water in the system allows for excellent function of the ion exchange resins.

The existing fleet of rotary compressors would require extensive piping modifications for use with ion-exchange filtration systems such as those described in the prior art, making them practically non-functional. Enclosures surrounding most compressors make the installation of large auxiliary equipment difficult or impractical, if possible at all. The filter device of the present invention combines the function of particulate filtration with ion exchange removal of acid from a compressor lubricant in a single disposable element. This facilitates easily retrofitting the roughly 100,000 compressors that are currently in service in the US alone, typically with sump capacities varying from two to sixty gallons.

As previously described, polyglycol and polyglycol/ester blend air compressor lubricant life is currently limited only by the accumulation of acid in the fluid. The present invention effectively removes the acid resulting in greatly extended, if not virtually indefinite fluid life in rotary compressors. The present invention incorporates a spin-on filter device containing ion exchange (acid absorption) media that will continuously remove the acid from the rotary screw air compressor fluid. Supporting laboratory tests have shown that ion exchange media equal to approximately 1-2 percent by weight of the amount of lubricant fluid present in the system will prevent acid levels from rising significantly for over 4000 hours without changing the ion exchange media (see, FIG. 1). The condition of the fluid and filter may be monitored, as will be described later, to alert the operator for the need to change the filter element. When needed, the spin-on filter device may easily be replaced, and the process repeated, extending the life of the fluid almost indefinitely. Polyglycols and polyglycol/ester blend fluids are unique in that they do not normally increase significantly in viscosity during extended use, unlike hydrocarbon based fluids. Therefore, the present invention achieves removal of the acid, which is the only obstacle preventing indefinite use of the polyglycol or polyglycol/ester blend fluid. Unexpectedly, the life of polyalphaolefin type fluids has also been shown to be increased substantially by the system of the present invention.

Another key part of the invention involves fluid flow. From a practical standpoint, the most preferred design of the system would ideally engage only a side stream of 1-10 percent of the fluid flow through the system, with the other 90-99 percent of the flow bypassing the acid removal filter. This could be accomplished with either an internal bypass in the canister, or with external piping. High fluid velocities through the filter may result in agitation and damage to the resin beads, and particles passing downstream. The compressors to which the present system would be affixed would be equipped to place the acid removal filter upstream of the common existing particulate filter employed on all rotary screw air compressors (see, FIG. 4).

In automotive applications, a “bypass” filter is also commonly used to filter a portion of the fluid flow for the purpose of removing wear metals, dirt, and other particulate matter. The uniqueness of the filter device of the present invention is the application of similar filtration hardware and piping to acid removal, and the use of ion exchange resins that are commercially available, but have not been applied to acid removal in polyglycols or polyglycol/ester blends in air compressors.

The ion exchange media may be retained in the spin-on filter by a fine wire mesh, as shown in the preferred embodiment in FIG. 3, or by any other mechanical means. In the filter device illustrated in FIG. 3 the functions of acid removal and particulate filtration are combined in a single, spin-on disposable device. An alternate design to the filter device may filter simplify the design and allow the particulate filter itself to be used to retain the ion exchange resin beads. Either of these would allow this invention to be retrofitted to older air compressors. Order compressors currently have only one attachment for filters. With the present invention, a single filter device allows both particulate and acid filtration to be accomplished in one filter cartridge. New compressors may be fitted with a single attachment, or preferably, be fitted with an additional attachment for a separate ion exchange filter cartridge in addition to the spin-on automotive style lubricant filter cartridge currently used.

A final component of the system of the present invention is the measurement of lubricant fluid properties and use of the measurements to determine filter change intervals and fluid condition on each compressor. Because of varying temperatures and contaminant levels in incoming air, the filter life will vary greatly from machine to machine.

The capacitance probe used in the present invention is preferably installed in the direct passage of the fluid flow, most preferably downstream from the particulate filter. This instrumentation feeds a variable voltage or current signal to the existing compressor microprocessor, which compares the signal to preset alarm points for changing filters or fluid. Instrumentation used to measure lubricant fluid's properties was based on the dielectric analysis. This was done conveniently using a Hewlett Packard 4194A and a Gilian LD-3 cell. This arrangement was used to measure the capacitance of the fluids at frequencies ranging from 0.1 MHz to 15 MHz. The preferred range for measurement is from 5 to 15 MHz, although the measurements can conducted at frequencies between 50 kHz and 200 MHz. Both dielectric constant and dissipation factor are effective determinants of TAN in these frequency ranges. Increases in dielectric constant and higher dissipation factor reliably correspond to high TAN in the lubricant.

The present invention eliminates the problems and obstacles to extended lubricant life previously outlined, while offering the following additional benefits:

(1) ease of use and replacement by incorporating a filter design similar to a spin-on automotive style particulate oil filter.

(2) the present invention provides high efficiency of acid absorption with polyglycol fluids by incorporating DOWEX™ WBA-2 resin. This resin substantially delays or reduces the increase in acid levels when used at a ratio of 1 to 5 parts by weight ion exchange resin to 100 parts by weight lubricant, for a period of 4000 hours. At about this time, the filter is changed. DOWEX™ WBA-2 resin is an ion exchange resin sold by The Dow Chemical Company.

(3) the preferred ion exchange resin, DOWEX™ WBA-2 resin, absorbs acid by reacting with ammonium ions and does not release metal ions into the lubricant. Other similar resins are expected to yield similar results.

(4) the present invention adapts easily to existing compressors, when the single spin-on element, combining ion exchange media with particulate filtration is used.

(5) the compact nature of the present invention allows it to fit within the existing compressor housing, rather than requiring large external apparatus and additional piping.

(6) the invention offers the additional benefit when used with polyglycol and polyglycol ester blends of greatly or indefinitely extending fluid life. Some improvement in PAO synthetic hydrocarbon fluids has also been shown to occur.

(7) disposable standard filter cartridges greatly reduce labor, and are readily disposed of, just as particulate lubricant filters are currently disposed of

(8) savings in disposal of lubricant, and an environmental benefit results from the elimination or extension of fluid changes in rotary air compressors.

(9) the present invention allows the effective use of rotary air compressors in environments where ingestion of acid gases currently makes them impractical, due to the requirement for frequent fluid changes, and corrosive attack of acids on the bearings and other parts of the compressor unit.

(10) when used as a system on rotary compressors with polyglycol or polyglycol/ester blended lubricants, the need for water removal processes prior to using the resin is eliminated. Due to solubility of water in the polyglycol fluid, the water is gradually dissolved in the fluid and excess levels removed by the air passing through the compressor.

All parts, percentages and ratios herein are by weight unless otherwise indicated.

The invention will be further clarified by a consideration of the following examples which are intended to be purely exemplary of the present invention.

### EXAMPLES

In the Examples that follow a long life formulation of polyglycol/ester lubricant fluid was used. Such lubricant fluids demonstrated fluid life of greater than 8,000 hours, or approximately one year in laboratory tests at 120° C.

The ion exchange media used in the Examples was 1 percent, 2 percent, and 5 percent by weight (wet) DOWEX™ WBA-2 resin. This resin was tested with new and used samples of commercially available (Sullube® and Ultra Coolant®) polyglycol/ester blend compressor lubricants. Samples were contacted at 248° F. and TAN measurements were taken periodically. In the used samples: 1 percent by weight of DOWEX™ WBA-2 resin reduced the TAN of a depleted sample from 1.0 TAN to 0.41 TAN in 216 hours. In further tests with new lubricant samples, DOWEX™ WBA-2 resin was effective in delaying the increase of TAN at levels of 1-5 percent by weight, as shown in FIG. 1. In this test, samples containing 2 percent by weight DOWEX™ WBA-2 resin showed an average TAN of 0.27 as compared to 0.47 TAN for a control containing no resin after 4368 hours. These tests were conducted at a temperature of 120° C., accelerating the rate of degradation by approximately a factor of four as compared to actual use in a compressor. More detailed results of testing are described in Table 5.

Samples of used compressor fluid, taken directly from compressors run for varying periods of time were measured by use of a capacitance probe, establishing the practicality of controlling this system by use of this measurement.

### Example 1

This example demonstrates the use of the combination filter device shown in FIG. 3 for the in-situ removal of acid from the compressor lubricant fluid. The combined filter device is used as a retrofit, replacing the existing particulate filter on a compressor. The filter (shown in FIG. 3) is simply screwed in place, as a replacement for the existing disposable cartridge oil filter. The full lubricant fluid flow enters the spin-on filter device (6). The unique feature of the filter device is the containment of ion exchange media (1) in the filter device; in such a way as to allow fluid to enter a mesh (8) or other means of containment and contact the ion exchange media, as shown in FIG. 3. The mesh is substantially finer than the size of the ion exchange media beads. The amount of ion exchange media contained in the filter device is equal to 0.1-20 percent, and preferably 1-5 percent by weight of the amount of lubricant fluid in the system. In this example, a filter containing 400 grams wet weight of the DOWEX™ WBA-2 resin is suitable for a compressor containing forty liters of polyglycol/ester lubricant fluid, for a time period of about 4000 hours. After this time, the filter may be replaced. A filter shown in FIG. 4 could be applied to existing compressors, equipment or vehicles for even greater resin capacity. The effectiveness of the acid removal by the filtration device used in Example 1 is demonstrated in FIG. 5.

### Example 2

This example demonstrates the use of the system of the present invention for monitoring and extending the life of the lubricant fluid in the compressor. The system involves the use of a preferred lubricant fluid, the filtration device, and the monitoring and measurement means. This allows for the measuring the performance of the lubricant fluid and filter device and alerting the user of the need to change the filter device by a simple electronic measurement, consisting of a probe that detects the conductivity, capacitance, dielectric constant, resistance, or other electrical properties of the fluid.

The removal of acids from the lubricant fluid results in the TAN of the lubricant fluid remaining in the usable range for an extended period of time, effectively and substantially lengthening the life of the lubricant fluid and ion exchange filter devices in this application.

The system used in this example incorporates a separate spin-on particulate filter (5), and is illustrated in FIG. 2. In this system, a portion of the fluid enters an acid filter device (3). The fluid contacts the ion exchange media that is contained at the inlet and along the outlet tube by a mesh to prevent loss of media. Only a portion of the fluid, 1-20 percent, and preferably about 1 percent enters the element on each pass through the filtration device, to avoid turbulence in the filter. Higher levels of resin are even more effective, but require a larger filter housing. The remainder of the fluid bypasses this filtration device. In a rotary compressor for example, the entire fluid reservoir circulates at a rate of about 1 pass per minute, so partial flow is preferred, rather than full flow. All of the fluid passes through the spin-on particulate filter (5) and back to the oil cooler and compressor unit (7). The benefit of this system for new compressors is the containment of a larger amount of ion exchange media, and the ability to change it separately as needed without changing the particulate filter. The acid filter device (3) itself is illustrated in greater detail in FIG. 4. Also, just as in the combined filter device used in Example 1, DOWEX™ WBA-2 resin or other suitable ion exchange resin is preferred as the acid removal media.

The lubricant fluid flows to the acid spin-on filter device (3) from the compressor sump (1). A capacitance or conductivity probe (6) is installed in the lubricant fluid flow, generating an electrical signal. The lubricant fluid leaving the filter device goes on to the oil cooler and compressor unit. The electrical signal from the probe is conducted by wire to the on-board microprocesssor/computer (8) capable of monitoring additional inputs, and giving alarms based on those inputs. The computer is programmed to monitor the electrical signal from the capacitance, or alternately conductivity or dielectric constant. A bypass valve (2) contained in the mounting head (2) generating a slight pressure drop allows 95-99 percent of the lubricant fluid to bypass the acid filter. The mounting head (4) for the spin-on filter device (5) requires full flow through this filter device. The spin on particulate filter device (5) is a standard, commercially available particulate filter. A capacitance or conductivity probe (6) is installed in the lubrication flow, generating an electrical signal for the computer (8). Lubricating fluid leaving the filter devices goes on to the oil cooler and compressor unit (7). The electrical signal from the probe (6) is conducted by wire to the on-board microprocessor/computer (8). This microprocessor is already in place on current model compressors, and capable of monitoring additional inputs and giving alarms based on those inputs. The computer is programmed to monitor the electrical signal from a capacitance, or alternately conductivity or dielectric constant

The effectiveness of the acid removal by the filtration media used in this example is demonstrated in FIG. 1. FIG. 1 plots the increase of TAN in Polyglycol/ester fluid at 248° F. with the addition of noted percent DOWEX™ WBA-2 resin, demonstrating effectiveness of the resin in removal of acid, and extending life of the lubricant fluid. FIG. 5 shows increasing effectiveness, in terms of increasing filter life with increasing levels of resin.

The following electrical properties were measured with the capacitance probe in this example and used to monitor the condition of the lubricant fluid.

Dielectric constants with polyglycol/ester compressor fluids were measured at 15 MHz frequency and the results obtained are given in Table 1 below.

TABLE 1
Relationship of TAN to Dielectric Constant
of a polyglycol/ester lubricant

| | Total Acid | Dielectric | Frequency |
|---|---|---|---|
| Sample # | Number | Constant | in MHz |
| Unused (Dry) | 0.10 | 5.07 | 15 |
| 588.5 | 0.14 | 5.59 | 15 |
| 586.5 | 0.14 | 5.61 | 15 |
| 593.3 | 1.0 | 5.89 | 15 |
| 592.5 | 4.0 | 6.40 | 15 |

As can be seen from Table 1, dielectric constants ranged from 5.07 for the lubricant fluid having a total acid number (TAN) of 0.1, to 6.40 for used fluid with a TAN of 4.0.

Dielectric constants with polyglycol/ester lubricant fluids were also measured at 0.1 MHz frequency and the results obtained are given in Table 2 below.

TABLE 2
Relationship of TAN to Dielectric Constant
of a polyglycol/ester lubricant

| | Total Acid | Dielectric | Frequency |
|---|---|---|---|
| Sample # | Number | Constant | in MHz |
| Unused (Dry) | 0.10 | 4.84 | 0.1 |
| 588.5 | 0.14 | 5.30 | 0.1 |
| 586.5 | 0.14 | 5.34 | 0.1 |
| 593.3 | 1.0 | 5.75 | 0.1 |
| 592.5 | 4.0 | 6.20 | 0.1 |

As can be seen from Table 2, dielectric constants ranged from 4.84 for the lubricant fluid having a TAN of 0.1, to 6.20 for used fluid with a TAN of 4.0.

The measurement of dielectric constants would also alert to contamination of the system with some types of impurities, although it would not distinguish between causes of failure.

Measuring the dissipation factor also monitored the lubricant fluid condition. Dissipation factor is an effective method of measuring TAN, with less measurement variation due to varying moisture content in the sample. Dissipation factors were measured at 15 MHz frequency and ranged from 0.066 for lubricant fluid having a TAN of 0.10 to 0.098 for lubricant fluid with a TAN of 4.0, as shown in Table 3 below.

TABLE 3
Relationship of TAN to Dissipation Factor
of a polyglycol/ester lubricant

| | Total Acid | Dissipation Factor | Frequency |
|---|---|---|---|
| Sample # | Number | Tangent Delta | in MHz |
| Unused (Dry) | 0.10 | 0.066 | 15 |
| 588.5 | 0.14 | 0.067 | 15 |
| 586.5 | 0.14 | 0.067 | 15 |
| 593.3 | 1.0 | 0.084 | 15 |
| 592.5 | 4.0 | 0.098 | 15 |

The dissipation factors were also measured at 8.7 MHz frequency and ranged from 0.044 for lubricant fluid having a TAN of 0.10 to 0.067 for lubricant fluid with an acid number of 4.0, as shown in Table 4 below.

TABLE 4
Relationship of TAN to Dissipation Factor
of a polyglycol/ester lubricant

| | Total Acid | Dissipation Factor | Frequency |
|---|---|---|---|
| Sample # | Number | Tangent Delta | in MHz |
| Unused (Dry) | 0.10 | 0.044 | 8.7 |
| 588.5 | 0.14 | 0.044 | 8.7 |
| 586.5 | 0.14 | 0.044 | 8.7 |
| 593.3 | 1.0 | 0.059 | 8.7 |
| 592.5 | 4.0 | 0.067 | 8.7 |

Other embodiments of the invention will be apparent to those skilled in the art from a consideration of this specification or practice of the invention disclosed herein. It is intended that the specification and examples be considered as exemplary only, with the true scope and, spirit of the invention being indicated by the following claims.

What is claimed is:

1. A system for the in-situ purification and monitoring of the condition of a lubricant fluid used in a rotary screw or centrifugal air compressor said system being functionally incorporated into the rotary screw or centrifugal air compressor and comprising (a) at least one filter device capable of removing an acid from the lubricant fluid, (b) an electrical probe for electronically monitoring the condition of the lubricating fluid and communicating electrical signal to an electrical signal processing means, and (c) an electrical signal processing means for processing electrical signal received from the electrical probe and alerting to the need for the change of the filter device or the lubricating fluid.

2. The system according to claim 1 wherein said at least one filter device comprises (a) a canister housing, (b) an ion exchange resin inside the canister housing and enclosed by a fine metal mesh at each inlet to allow lubricant fluid ingress and egress, (c) at least one lubricant fluid inlet, (d) lubricant fluid outlet, and (e) an O-ring around circumference of the filter device to seal it up to a compressor mounting hardware.

3. The system according to claim 1 wherein said at least one filter device is a dual filter device comprising (a) a canister housing, (b) an ion exchange resin inside the canister housing and enclosed by fine metal mesh at each inlet to allow lubricant fluid ingress and egress, (c) a standard particulate filter media inside the canister housing and surrounded by the ion exchange resin, (d) at least one lubricant fluid inlet, (e) lubricant fluid outlet, and (f) an O-ring around circumference of the filter device to seal it up to a compressor mounting hardware.

4. The system according to claim 2 or claim 3, further comprising a standard particulate filter device positioned downstream flow from said at least one disposable spin-on filter device.

5. The system according to any one of claim 1 to claim 4, wherein the electrical probe is located in direct passage of the lubricant fluid flow of the filter device capable of removing the acid from the lubricant fluid.

6. The system according to claim 5, wherein the electrical probe continuously monitors the lubricant fluid condition by measuring conductivity, capacitance, dielectric constant or electrical resistance of the lubricant fluid.

7. The system according to claim 5, wherein the electrical probe intermittently monitors the lubricant fluid condition by measuring conductivity, capacitance, dielectric constant or electric resistance of the lubricant fluid.

8. The system of any one of claims 1 to 7 wherein the means for processing electrical signals from the probe is a computer or microprocessor installed on the compressor and integrated into an alarm system.

9. The system according to any one of claims 1 to 8, wherein the lubricant fluid is a long life lubricant fluid.

10. The system of claim 9, wherein the long life lubricant fluid is a polyoxyalkylene glycol, polyol ester, polyalphaolefin based lubricant, or any blend thereof.

11. A method for the in-situ purifying and monitoring the condition of a lubricant fluid of a rotary screw or centrifugal air compressor said method comprising passing the lubricant fluid through the system of claim 1.

12. The method of claim 11 wherein the dielectric constant, dissipation factor or electrical resistance of the lubricant fluid is measured to monitor the condition of the lubricant fluid.
